(19) United States
(12) Patent Application Publication
(10) Pub. No.: US 2026/0169061 A1
(43) Pub. Date: Jun. 18, 2026

(54) SILICON PHOTONIC TEST PLUG-IN MODULE AND SILICON PHOTONIC TEST EQUIPMENT

(71) Applicant: King Yuan Electronics Co., Ltd., Hsin-Chu (TW)

(72) Inventors: Kuo-Jung WU, Hsin-Chu (TW); Hsing Yueh LIANG, Hsin-Chu (TW); Po Wei LIAO, Hsin-Chu (TW); Hung-Chi WEI, Hsin-Chu (TW); Yi Ting WANG, Hsin-Chu (TW)

(21) Appl. No.: 19/310,906

(22) Filed: Aug. 26, 2025

(30) Foreign Application Priority Data
Dec. 18, 2024 (TW) 113149484

(51) Int. Cl. G01R 31/28

(52) U.S. Cl. CPC G01R 31/2884; G01R 31/2887; G01R 31/2889; G01R 31/2891

(57) ABSTRACT

A silicon photonic test plug-in module includes a carrier board, a floating moving device, a mating connector and an accommodating seat. The floating moving device is movably installed on the carrier board, the mating connector is floatingly installed in the floating moving device, and the accommodating seat is located adjacent to the carrier board to fix a silicon photonic device, and the mating connector is automatically aligned with a silicon photonic device connector of the silicon photonic device. In addition, a silicon photonic test equipment including the silicon photonic test plug-in module is also disclosed herein.

### RELATED APPLICATIONS

This application claims priority to Taiwan Application Serial Number 113149484, filed Dec. 18, 2024, the disclosure of which is incorporated herein by reference in its entirety.

### TECHNICAL FIELD

The present disclosure relates to a silicon photonic test plug-in module. More particularly, the present disclosure relates to a silicon photonic test equipment having a silicon photonic test plug-in module.

### BACKGROUND

With the increasing advancement of technology, silicon photonics having the characteristics of high performance, low power consumption and small size, is rapidly becoming the focus of the industry. Silicon photonics refers to the integration of photonic components able to modulate photons into silicon-based semiconductors, allowing for the simultaneous collaboration of Electronic Integrated Circuits (EICs) and Photonic Integrated Circuits (PICs) within a chip or system.

Currently, the vast majority of silicon photonic products that have begun mass production are transceivers utilized for long-distance communication, which include functional components for transmitting/receiving electrical/optical signals and converting and processing information.

Co-Packaged Optics (CPO) may directly package silicon chips for computing and optical transceiver modules together using advanced packaging, thereby reducing component size, lowering power consumption, and improving photoelectric conversion efficiency and accuracy.

However, when testing silicon photonic components, the interface of the silicon photonic chip utilizes optical connectors. If alignment errors occur during the mating of optical connectors, the alignment errors may easily lead to abnormal or incorrect testing. If the silicon photonic chip is tested in an unpackaged state, the optical connector and the processing integrated circuit are only connected by optical fibers. When picking and placing the components to test the silicon photonic chip, the optical fibers may be easily pulled and damaged.

How to develop a solution to improve the aforementioned shortcomings and inconveniences is an urgent and important issue for the relevant industries.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide a silicon photonic test plug-in module able to stably and accurately align optical connectors and mating connectors, and further improve the accuracy of silicon photonic device testing.

To achieve these and other advantages and in accordance with the objective of the embodiments of the present invention, as the embodiment broadly describes herein, the embodiments of the present invention provides a silicon photonic test plug-in module including a carrier board, a floating moving device, a mating connector, and an accommodating seat. The floating moving device is movably installed on the carrier board, the mating connector is floatingly installed in the floating moving device, and the accommodating seat is adjacent to the carrier board for fixing a silicon photonic device, while the mating connector automatically aligns with the silicon photonic device connector of the silicon photonic device.

In some embodiments, the floating moving device includes a moving outer frame, a plurality of floating supporting devices, and a plurality of elastic devices. The floating supporting devices are disposed in the moving outer frame for clamping the mating connector, and the elastic devices are installed between the moving outer frame and the floating supporting devices to allow the mating connector movable within the moving outer frame.

In some embodiments, the floating moving device further includes a positioning pin, and the carrier board includes a positioning hole, so that the mating connector is initially aligned with the silicon photonic device connector.

In some embodiments, the accommodating seat includes a movable positioning device to position the silicon photonic device on the accommodating seat.

In some embodiments, the accommodating seat further includes a third suction nozzle to fix the silicon photonic device on the accommodating seat.

In some embodiments, the accommodating seat further includes a first pressure sensor, disposed opposite to the movable positioning device, and the silicon photonic device is clamped between the movable positioning device and the first pressure sensor.

In some embodiments, the silicon photonic test plug-in module further includes a second pressure sensor, installed between the carrier board and the floating moving device, to measure an insertion force when the mating connector is connected to the silicon photonic device connector.

In some embodiments, the silicon photonic test equipment includes a silicon photonic testing machine and a sorting machine. The sorting machine is electrically connected to the silicon photonic testing machine, and the sorting machine includes the aforementioned silicon photonic test plug-in module, a test bench, a feeding module, a discharging module, a silicon photonic pick-and-place device, and a moving module. The test bench is utilized to test the silicon photonic device, and the feeding module is utilized to accommodate a plurality of silicon photonic devices to be tested, and the discharging module is utilized to accommodate a plurality of tested silicon photonic devices. The silicon photonic pick-and-place device is disposed between the silicon photonic test plug-in module, the feeding module, and the discharging module for moving the silicon photonic devices to be tested and the tested silicon photonic devices. In addition, the silicon photonic test plug-in module is installed on the moving module for moving the silicon photonic test plug-in module and the silicon photonic device on the silicon photonic test plug-in module to a position of the test bench.

In some embodiments, the moving module includes a first moving device, a second moving device, and a third moving device. The second moving device is disposed perpendicular to the first moving device, and the third moving device is disposed perpendicular to the first moving device and the second moving device.

In some embodiments, the third moving device includes a six-degree-of-freedom moving device.

In some embodiments, the silicon photonic test equipment further includes a first optical identifier, installed on one side of the feeding module adjacent to the silicon photonic test plug-in module, to identify a direction and identification code of the silicon photonic device.

In some embodiments, the silicon photonic test equipment further includes a second optical identifier, installed on the test bench, to identify a structure and position of the silicon photonic device before and after testing.

In some embodiments, the silicon photonic test equipment further includes a third optical identifier, disposed adjacent to the discharging module, to detect a lower surface and four side surfaces of the chip of the silicon photonic device.

In some embodiments, the silicon photonic test equipment further includes a fourth optical identifier and an optical identifier bracket. The optical identifier bracket fixes the fourth optical identifier to the third moving device to detect a position of the test terminals of the test head of the test bench for adjusting a position of the silicon photonic device.

In some embodiments, the silicon photonic test equipment further includes a fifth optical identifier, disposed above the feeding module, to guide the silicon photonic pick-and-place device to pick up the silicon photonic device.

In some embodiments, the silicon photonic pick-and-place device includes at least one suction nozzle to suck the silicon photonic device.

In some embodiments, the aforementioned suction nozzle includes a first suction nozzle and a second suction nozzle. The first suction nozzle is utilized to suck the silicon photonic device connector of the silicon photonic device, and the second suction nozzle is utilized to suck the silicon photonic chip of the silicon photonic device.

In some embodiments, the silicon photonic device further includes a substrate and an application-specific integrated circuit, wherein the application-specific integrated circuit and the silicon photonic chip are fixed on the substrate.

In some embodiments, the silicon photonic test plug-in module further includes a plurality of probes to electrically connect the application-specific integrated circuit.

In some embodiments, the silicon photonic test plug-in module further includes a pressure plate to press against the silicon photonic device.

Hence, the aforementioned silicon photonic test plug-in module and silicon photonic test equipment may conveniently and stably perform silicon photonic device testing. Regardless of whether the silicon photonic device is packaged or unpackaged, the optical connector and the mating connector of the silicon photonic device may be accurately connected, reducing optical fiber damage and improving test quality.

### BRIEF DESCRIPTION OF THE DRAWINGS

The disclosure may be more fully understood by reading the following detailed description of the embodiment, with reference made to the accompanying drawings as follows:

FIG. 1 is a perspective view of a silicon photonic test equipment according to an embodiment of the present invention;

FIG. 2 is a perspective view of a silicon photonic test plug-in module of a silicon photonic test equipment according to an embodiment of the present invention;

FIG. 3 is a front view of a floating moving device of a silicon photonic test plug-in module of a silicon photonic test equipment according to an embodiment of the present invention;

FIG. 4 is a side view of some components of a silicon photonic test equipment according to an embodiment of the present invention;

FIG. 5A is a schematic diagram of a test head and chip terminals of a silicon photonic test equipment before electrical connection according to an embodiment of the present invention;

FIG. 5B is a schematic diagram of a test head and chip terminals of a silicon photonic test equipment after electrical connection according to an embodiment of the present invention;

FIG. 6 is a side view of a silicon photonic test plug-in module of a silicon photonic test equipment according to an embodiment of the present invention;

FIG. 7 is a side view of a silicon photonic test plug-in module of a silicon photonic test equipment according to another embodiment of the present invention; and

FIG. 8 is a top view of the silicon photonic test equipment of FIG. 1.

### DETAILED DESCRIPTION OF THE PREFERRED EMBODIMENT

The following is a detailed description of the embodiments in conjunction with the accompanying drawings, but the provided embodiments are not intended to limit the scope of the disclosure, and the description of the structure and operation is not utilized to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are utilized in the drawings and the description to refer to the same or like parts.

In addition, the terms utilized in the entire description and the scope of the patent application, unless otherwise specified, usually have the usual meaning of each term utilized in this field, in the content disclosed here and in the special content. Some terms utilized to describe the disclosure are discussed below or elsewhere in this specification to provide additional guidance to those skilled in the art in the disclosure.

In the implementation mode and the scope of the present application, unless the article is specifically limited in the context, “a” and “the” may generally refer to a single or pluralities. In the steps, the numbering is only utilized to conveniently describe the steps, rather than to limit the sequence and implementation.

Secondly, the words “comprising”, “including”, “having”, “containing” and the like utilized in the present application are all open language, meaning including but not limited thereto.

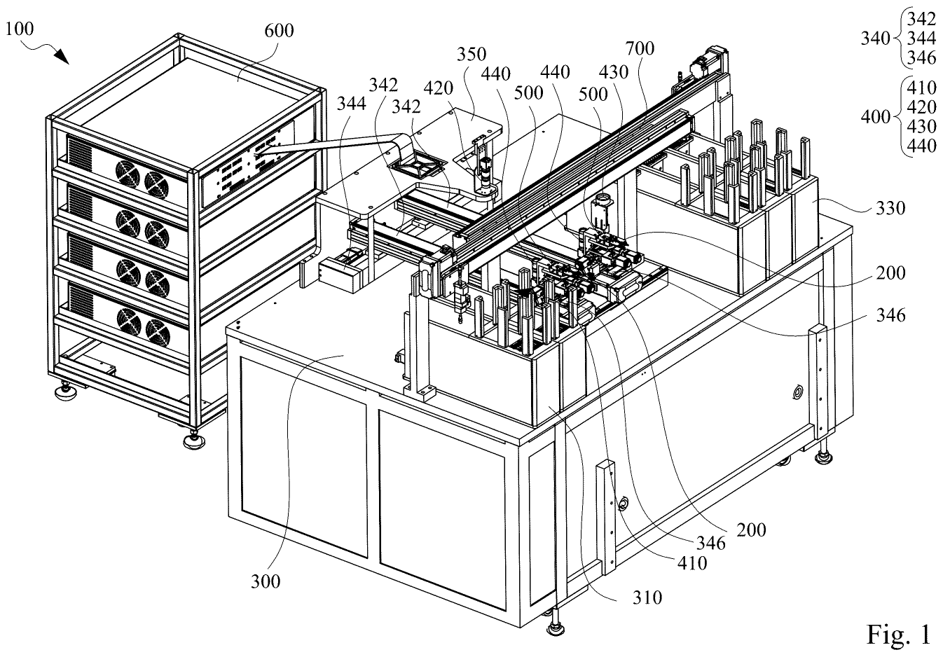

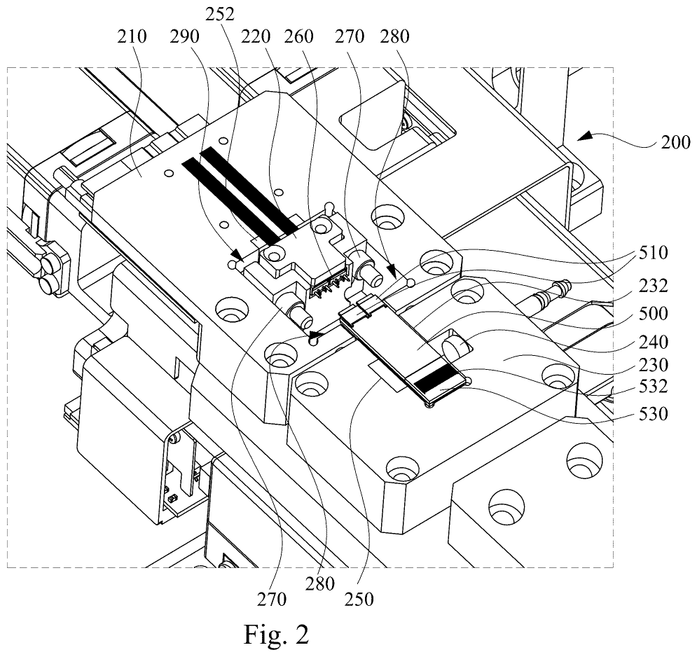

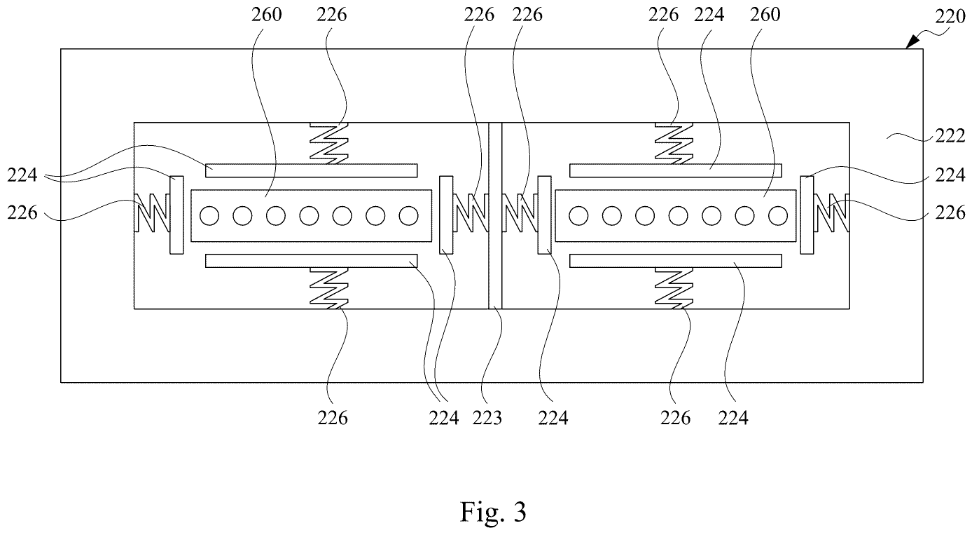

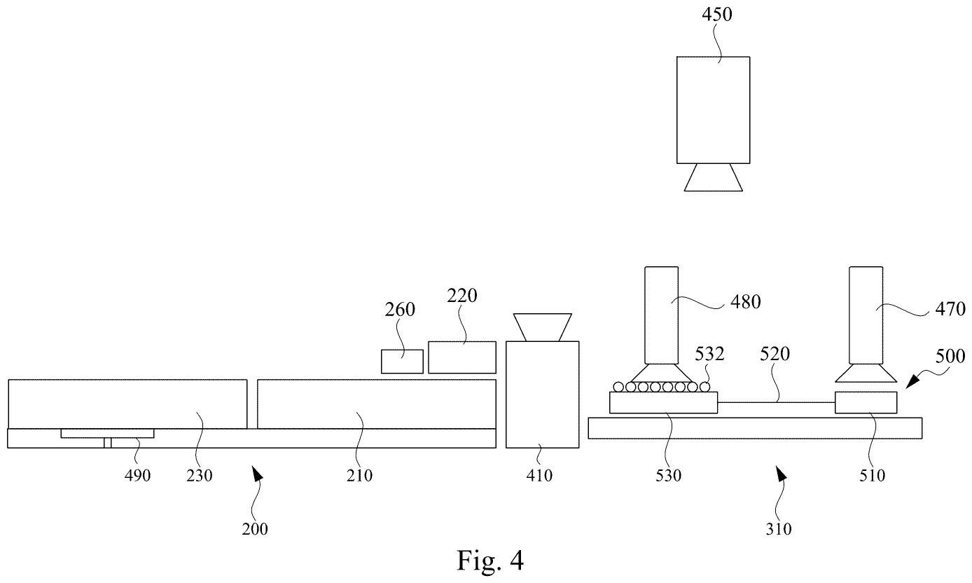

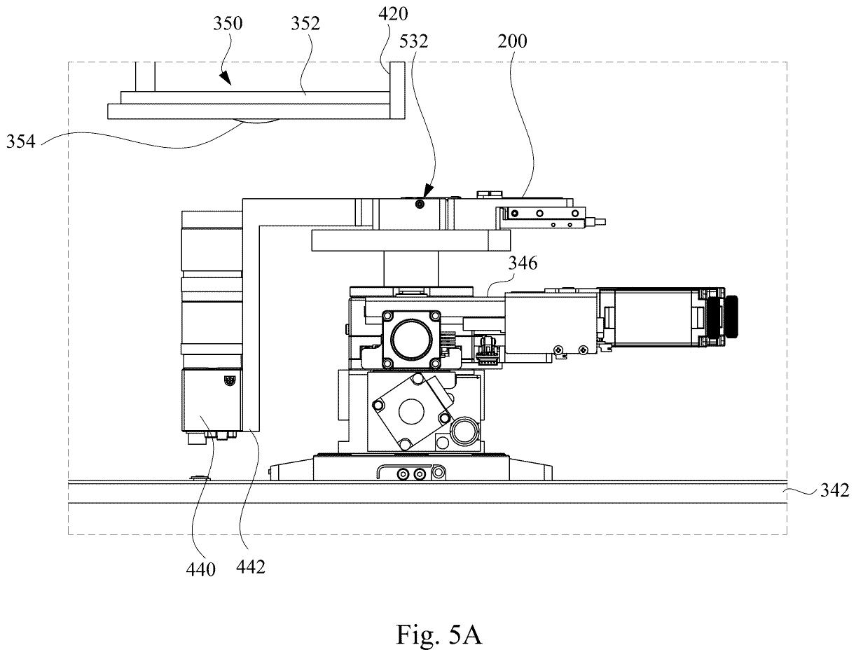

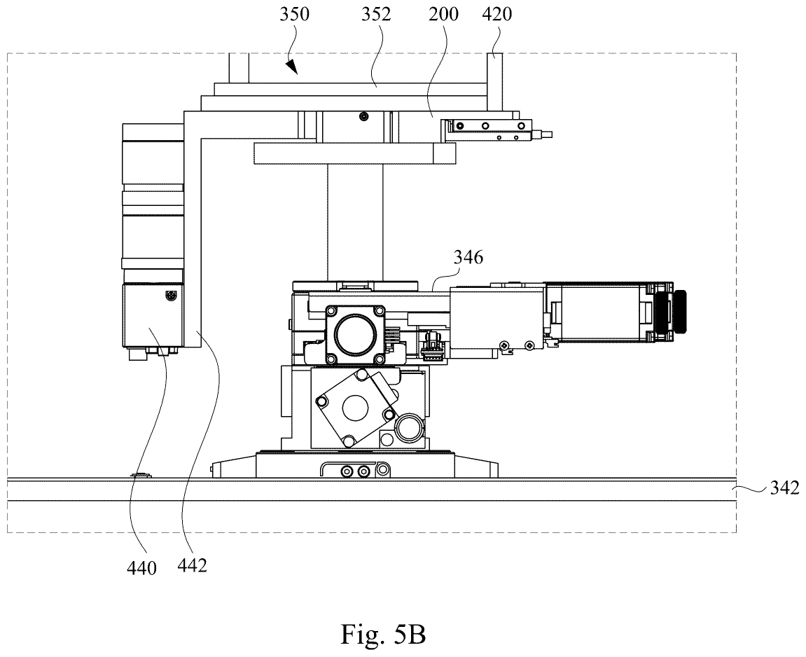

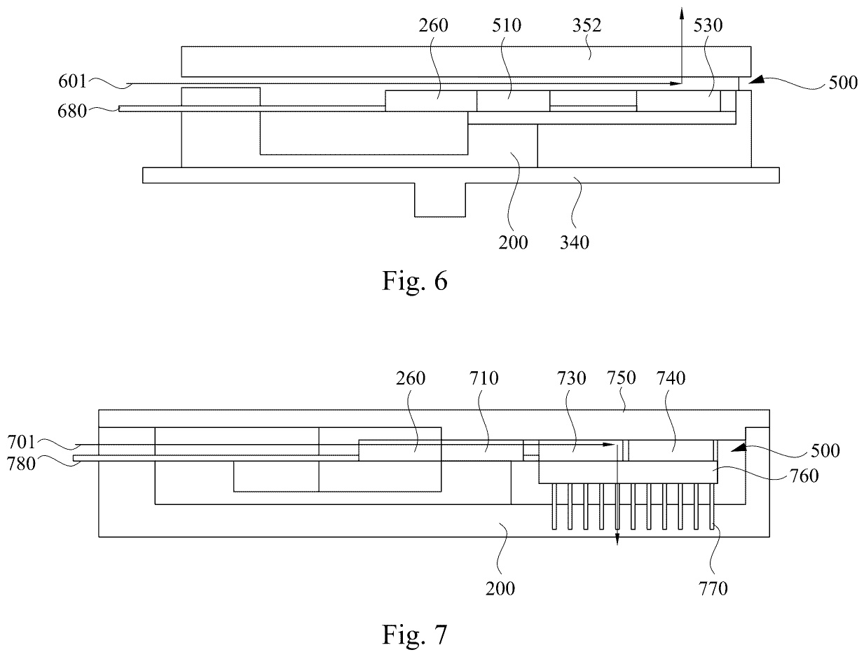

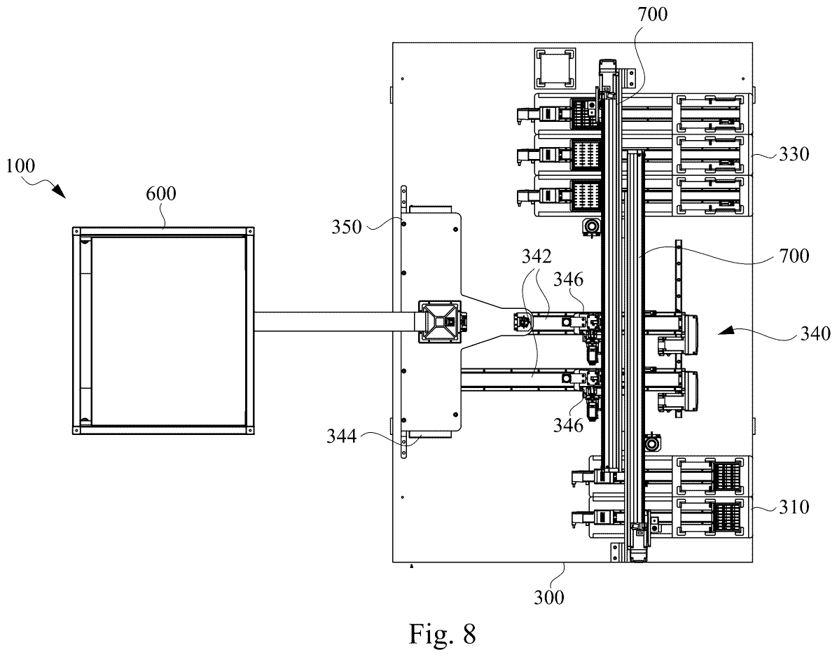

FIG. 1 is a perspective view of a silicon photonic test equipment, FIG. 2 is a perspective view of a silicon photonic test plug-in module, FIG. 3 is a front view of a floating moving device of the silicon photonic test plug-in module of the silicon photonic test equipment, FIG. 4 is a side view of some components of the silicon photonic test equipment, and FIGS. 5A and 5B are schematic diagrams of a test head and chip terminals of the silicon photonic test equipment before and after electrical connection. In addition, FIG. 6 is a side view of a silicon photonic test plug-in module of a silicon photonic test equipment according to an embodiment of the present invention, and FIG. 7 is a side view of a silicon photonic test plug-in module of a silicon photonic test equipment according to another embodiment of the present invention. FIG. 8 is a top view of the silicon photonic test equipment of FIG. 1.

Referring to FIGS. 1 and 8, as shown in the figures, the silicon photonic test equipment 100 includes a silicon photonic testing machine 600 and a sorting machine 300. The sorting machine 300 is electrically connected to the silicon photonic testing machine 600.

The sorting machine 300 includes a feeding module 310, a discharging module 330, a silicon photonic pick-and-place device 700, a test bench 350, a silicon photonic test plug-in module 200, and a moving module 340. The feeding module 310 is utilized to accommodate a plurality of silicon photonic devices 500 to be tested, and the discharging module 330 is utilized to accommodate and sort a plurality of tested silicon photonic devices 500.

The silicon photonic pick-and-place device 700 is disposed between the silicon photonic test plug-in module 200, the feeding module 310, and the discharging module 330 to move the silicon photonic devices 500 to be tested and the tested silicon photonic devices 500.

The test bench 350 is utilized to test the silicon photonic device 500, and the silicon photonic test plug-in module 200 is utilized to accommodate the silicon photonic device 500 and connect the silicon photonic device connector 510 of the silicon photonic device 500 to the mating connector 260 on the silicon photonic test plug-in module 200.

The silicon photonic test plug-in module 200 is installed on the moving module 340. The moving module 340 is utilized to move the silicon photonic test plug-in module 200 and the silicon photonic device 500 on the silicon photonic test plug-in module 200 to the position of the test bench 350 for testing the silicon photonic device 500.

The test bench 350, the feeding module 310, and the discharging module 330 of the sorting machine 300 are separated by a distance. By setting the moving module 340, the silicon photonic device 500 is transported for testing, and the testing and transportation of different silicon photonic devices 500 are realized, thereby effectively improving testing efficiency.

The silicon photonic testing machine 600 includes an optical signal generator and an optical switch, connected to the mating connector 260 through an optical fiber to transmit optical signals to the silicon photonic device 500. After photoelectric conversion, the silicon photonic device 500 transmits electrical signals to the test bench 350, and then the test bench 350 sends the signals back to the silicon photonic testing machine 600 to determine the test signals of the silicon photonic device 500.

Further referring to FIG. 2, as shown in the figure, the silicon photonic test plug-in module 200 includes a carrier board 210, a floating moving device 220, a mating connector 260, and an accommodating seat 230.

The floating moving device 220 is movably installed on the carrier board 210, and the mating connector 260 is floatingly installed in the floating moving device 220. The accommodating seat 230 is located adjacent to the carrier board 210 and is utilized to fix a silicon photonic device 500. The mating connector 260 may automatically align with the silicon photonic device connector 510 of the silicon photonic device 500.

In some embodiments, the carrier board 210 is provided with a recess 290, and the floating moving device 220 is movably installed in the recess 290 of the carrier board 210, but not limited thereto. In addition, the accommodating seat 230 is provided with an accommodating socket 232, and the silicon photonic device 500 is fixed in the accommodating socket 232 of the accommodating seat 230, without departing from the spirit and scope of the present invention.

In some embodiments, the carrier board 210 and the accommodating seat 230 may be manufactured separately and then installed, or may be formed from a single substrate, without departing from the spirit and scope of the present invention.

In some embodiments, referring simultaneously to FIG. 3, as shown in the figure, the floating moving device 220 includes a moving outer frame 222, a plurality of floating supporting devices 224, and a plurality of elastic devices 226. The floating supporting devices 224 are disposed within the moving outer frame 222 for clamping the mating connector 260, and the elastic devices 226 are installed between the moving outer frame 222 and the floating supporting devices 224 to allow the mating connector 260 movable within the moving outer frame 222. In some embodiments, the moving outer frame 222 of the floating moving device 220 further includes an intermediate partition 223 to divide the moving outer frame 222 into a plurality of sections for separately installing a plurality of floating supporting devices 224 and a plurality of elastic devices 226, thereby clamping a plurality of mating connectors 260, and the elastic devices 226 are installed between the moving outer frame 222 or the intermediate partition 223 and the floating supporting devices 224 to allow the plurality of mating connectors 260 movable within the moving outer frame 222.

In some embodiments, the floating supporting devices 224 surround the periphery of the mating connector 260, and the elastic devices 226 are also disposed around the periphery of the mating connector 260 and between the moving outer frame 222 and the floating supporting devices 224, effectively providing the clamping force required for clamping the mating connector 260, and allowing the mating connector 260 movable within the moving outer frame 222. Therefore, the guiding structures on the mating connector 260 and the silicon photonic device connector 510 may further align the mating connector 260 to the silicon photonic device connector 510 so as to improve the stability and accuracy of the connection.

Therefore, the floating supporting devices 224 and the elastic devices 226 may be arranged according to the number of mating connectors 260, allowing each mating connector 260 to float independently. A larger alignment range is provided so as to enable the mating connector 260 to accurately align to the silicon photonic device connector 510 of the silicon photonic device 500, thereby eliminating packaging errors of the silicon photonic device connector 510.

In some embodiments, the floating moving device 220 further includes a positioning pin 270, and the carrier board 210 includes a positioning hole 280. When the floating moving device 220 moves towards the accommodating seat 230 within the carrier board 210, the positioning pin 270 is inserted into the positioning hole 280, so that the mating connector 260 installed in the floating moving device 220 may be initially aligned with the silicon photonic device connector 510.

In some embodiments, the accommodating seat 230 includes a movable positioning device 240, located on one side of the silicon photonic device 500. When the silicon photonic device 500 is moved from the feeding module 310 to the accommodating seat 230, the movable positioning device 240 may gently press against the silicon photonic device 500, causing the silicon photonic device 500 to be pushed by the movable positioning device 240 to a specific position on the accommodating seat 230. Preferably, the silicon photonic device 500 is positioned within the accommodating socket 232 of the accommodating seat 230. For example, the silicon photonic device 500 may be positioned against one side of the accommodating socket 232, and the movable positioning device 240 may push the silicon photonic device 500 with the movable positioning device 240 to contact the side of the accommodating socket 232, and therefore the position of the silicon photonic device 500 within the accommodating socket 232 may be effectively fixed.

In some embodiments, the accommodating seat 230 further includes a first pressure sensor 250, disposed opposite to the movable positioning device 240. In addition, the silicon photonic device 500 is clamped between the movable positioning device 240 and the first pressure sensor 250. The first pressure sensor 250 measures the pressure applied by the movable positioning device 240 to the silicon photonic device 500 to confirm that the silicon photonic device 500 is clamped between the movable positioning device 240 and the first pressure sensor 250, and to avoid excessive pressure to damage the silicon photonic device 500. In some embodiments, the pressure applied by the movable positioning device 240 to the silicon photonic device 500 is approximately less than 20 grams, for example, between 10 grams and 20 grams, but not limited thereto.

In some embodiments, the accommodating seat 230 further includes a third suction nozzle 490. The third suction nozzle 490 may be a single-hole or multi-hole design to suck the silicon photonic device 500 and fix the silicon photonic device 500 on the accommodating seat 230. When the silicon photonic device 500 is transported and tested between the feeding module 310, the discharging module 330, and the test bench 350, the suction nozzle may ensure the silicon photonic device 500 be stably placed on the accommodating seat 230 without displacement.

In some embodiments, the silicon photonic test plug-in module 200 further includes a second pressure sensor 252, installed between the carrier board 210 and the floating moving device 220, to measure the insertion force when the mating connector 260 is connected to the silicon photonic device connector 510, preferably about 20 to 30 Newtons (N), but not limited thereto.

In some embodiments, the moving module 340 includes a first moving device 342, a second moving device 344, and a third moving device 346. Preferably, the first moving device 342, the second moving device 344, and the third moving device 346 are arranged perpendicular to each other, but not limited thereto.

In some embodiments, the first moving device 342 and the second moving device 344 are linear moving devices, and the third moving device 346 is preferably a moving device with six degrees of freedom, and preferably the third moving device 346 may move along three vertical directions and rotate in three vertical planes simultaneously.

Referring to FIGS. 1 and 8, a plurality of first moving devices 342 are provided. The plurality of first moving devices 342 may simultaneously transport and test the silicon photonic devices 500, thereby greatly shortening the waiting time for transporting the silicon photonic device 500 and improving testing efficiency. By setting the distance, the silicon photonic device 500 may be pre-connected to the mating connector 260 on the third moving device 346, effectively improving the testing efficiency of the silicon photonic device 500.

In one embodiment, when the silicon photonic device 500 is tested on the test bench 350, the first moving device 342, the second moving device 344, and the third moving device 346 may simultaneously transport untested silicon photonic devices 500 from the feeding module 310 to the test bench 350 for testing, or transport tested silicon photonic devices 500 from the test bench 350 to the discharging module 330 for sorting, simultaneously realizing the testing and transportation of different silicon photonic devices 500, greatly improving testing efficiency.

In some embodiments, the silicon photonic test equipment 100 includes an optical identification module 400, such as a first optical identifier 410, a second optical identifier 420, a third optical identifier 430, a fourth optical identifier 440, and/or a fifth optical identifier 450, but not limited thereto.

In some embodiments, the first optical identifier 410 is preferably installed on the side, adjacent to the silicon photonic test plug-in module 200, of the feeding module 310 to identify the direction and the identification code of the silicon photonic device 500, thereby determining whether the direction of the silicon photonic device 500 is correct and adjusting the position of the silicon photonic device 500 when the silicon photonic device 500 is placed into the accommodating seat 230.

In some embodiments, the second optical identifier 420 is preferably installed on the test bench 350 to identify the structure and the position of the silicon photonic device 500 before and after testing, thereby using the moving module 340 to adjust the position of the silicon photonic device 500.

In some embodiments, the third optical identifier 430 is preferably disposed adjacent to the discharging module 330 to detect whether there are defects in the appearance of the lower surface and four side surfaces of the chip of the silicon photonic device 500.

In some embodiments, referring simultaneously to FIGS. 5A and 5B, the silicon photonic test equipment 100 further includes an optical identifier bracket 442. The optical identifier bracket 442 fixes the fourth optical identifier 440 to the third moving device 346 and allows the fourth optical identifier 440 to move synchronously with the third moving device 346. The fourth optical identifier 440 detects the position of the test terminals 354 of the test head 352 of the test bench 350 to precisely adjust the position of the silicon photonic device 500, so that the chip terminals 532 on the silicon photonic device 500 are aligned with the test terminals 354 of the test head 352 of the test bench 350. Then, referring to FIG. 5B, the third moving device 346 moves upward, causing the test head 352 to electrically connect with the chip terminals 532.

In some embodiments, referring to FIG. 4, as shown in the figure, the fifth optical identifier 450 of the silicon photonic test equipment 100 is preferably disposed above the feeding module 310 to guide the silicon photonic pick-and-place device 700 to pick up the silicon photonic device 500 using a suction nozzle, so as to move the silicon photonic device 500 from the feeding module 310 to the silicon photonic test plug-in module 200, and to fix the silicon photonic device 500 on the accommodating seat 230 using the third suction nozzle 490.

In some embodiments, the suction nozzle of the silicon photonic pick-and-place device 700 may include one or more suction nozzles. When the silicon photonic device 500 is a fully packaged silicon photonic component, a single suction nozzle or a plurality of suction nozzles may be utilized to suck the silicon photonic device 500 to move the same. When the silicon photonic device 500 is an unpackaged silicon photonic component, the silicon photonic pick-and-place device 700 may utilize a plurality of suction nozzles to suck different parts of the silicon photonic device 500. For example, the silicon photonic device 500 shown in FIG. 4 includes at least one silicon photonic device connector 510, a silicon photonic chip 530, and an optical fiber 520. The optical fiber 520 is connected between the silicon photonic device connector 510 and the silicon photonic chip 530.

In some embodiments, the first suction nozzle 470 of the silicon photonic pick-and-place device 700 is utilized to suck the silicon photonic device connector 510 of the silicon photonic device 500, and the second suction nozzle 480 of the silicon photonic pick-and-place device 700 is utilized to suck the silicon photonic chip 530 of the silicon photonic device 500, so as to stably pick up and move the silicon photonic device 500.

In some embodiments, referring simultaneously to FIGS. 5A and 5B, after the fourth optical identifier 440 detects the positional image of the test terminals 354 of the test head 352 of the test bench 350, the third moving device 346 moves towards the test bench 350, and the second optical identifier 420 disposed on the test bench 350 captures an image of the contacts packaged on the silicon photonic device 500. Then, positions of the test terminals 354 of the test head 352 and the contacts packaged on the silicon photonic device 500 are matched through calculation. At this time, the first moving device 342 provides, for example, X-direction movement alignment, the second moving device 344 provides, for example, Y-direction movement alignment, and the third moving device 346 provides, for example, rotational alignment in the XY plane. After the XY plane position alignment is completed, the third moving device 346 adjusts the silicon photonic test plug-in module 200 in, for example, the Z-direction height. In other words, the third moving device 346 may provide degrees of freedom in the XY plane and the Z direction. In addition, the silicon photonic test plug-in module 200 may simultaneously have degrees of freedom in X, Y, Z, and the XY plane, thereby aligning the chip terminals 532 with the test terminals 354 to achieve precise electrical connection.

Therefore, since the contacts on the silicon photonic device 500 adopt micro-bump packaging, and the surface area of the micro-bumps is small and the arrangement thereof is relatively dense, high-precision probe contact is required. The cross-sectional area of the probes in the test head 352 is relatively small, so they may accurately and precisely contact the contacts on the silicon photonic device 500. Compared to traditional test sockets, the test head 352 of the present invention may provide more accurate electrical connections, thereby making the test results more precise.

Referring simultaneously to FIG. 6, as shown in the figure, when the silicon photonic device 500 is moved from the feeding module 310 to the silicon photonic test plug-in module 200, and the mating connector 260 mates with the silicon photonic device connector 510, the moving module 340 moves the silicon photonic device 500 so that the chip terminals 532 on the silicon photonic device 500 are electrically connected to the test terminals 354 of the test head 352 of the test bench 350 (refer also to FIGS. 5A and 5B). Then, using the optical fiber 680, the test signal is transmitted along the signal path 601, converted into an electrical signal by the silicon photonic device 500, and then transmitted from the chip terminals 532 on the silicon photonic device 500 to the silicon photonic testing machine 600 for signal testing of the silicon photonic device 500.

In addition, referring to FIG. 7, in some embodiments, the silicon photonic device 500 as shown further includes a silicon photonic device connector 710, a silicon photonic chip 730, an application-specific integrated circuit (ASIC) 740, and a substrate 760. The application-specific integrated circuit 740 and the silicon photonic chip 730 are fixed on the substrate 760.

In some embodiments, the silicon photonic test plug-in module 200 further includes a plurality of probes 770 and a pressure plate 750. The probes 770 are utilized to electrically connect the application-specific integrated circuit 740, and the pressure plate 750 is utilized to press against the silicon photonic device 500 to ensure a stable electrical connection between the silicon photonic device 500 and the probes 770.

When the silicon photonic device 500 is moved from the feeding module 310 to the silicon photonic test plug-in module 200, and the mating connector 260 mates with the silicon photonic device connector 710, the test signal is then transmitted using the optical fiber 780 along the signal path 701, converted into an electrical signal by the silicon photonic device 500, and then transmitted from the terminals of the substrate 760 of the silicon photonic device 500 to the silicon photonic testing machine 600 via the probes 770 for signal testing of the silicon photonic device 500.

In some embodiments, the aforementioned silicon photonic device connector may be a multi-fiber push-on connector (MPO connector), such as a multi-fiber termination push-on connector (MTP connector), without departing from the spirit and scope of the present invention.

Accordingly, the silicon photonic test plug-in module and the silicon photonic test equipment according to the present invention may conveniently and stably perform the silicon photonic device testing. Regardless of whether the silicon photonic device is packaged or unpackaged, the optical connector and the mating connector of the silicon photonic device may be accurately connected, thereby reducing optical fiber damage and improving test quality.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. A silicon photonic test plug-in module, comprising:
a carrier board;
a floating moving device movably installed on the carrier board;
a mating connector floatingly installed in the floating moving device; and
an accommodating seat adjacent to the carrier board for fixing a silicon photonic device, wherein the mating connector automatically aligns with a silicon photonic device connector of the silicon photonic device.

2. The silicon photonic test plug-in module as claimed in claim 1, wherein the floating moving device comprises:
a moving outer frame;
a plurality of floating supporting devices disposed in the moving outer frame for clamping the mating connector; and
a plurality of elastic devices installed between the moving outer frame and the floating supporting devices so that the mating connector is movable within the moving outer frame.

3. The silicon photonic test plug-in module as claimed in claim 2, wherein the floating moving device further comprises a positioning pin, and the carrier board comprises a positioning hole, so that the mating connector is initially aligned with the silicon photonic device connector.

4. The silicon photonic test plug-in module as claimed in claim 1, wherein the accommodating seat comprises a movable positioning device to position the silicon photonic device on the accommodating seat.

5. The silicon photonic test plug-in module as claimed in claim 4, wherein the accommodating seat further comprises a third suction nozzle to fix the silicon photonic device on the accommodating seat.

6. The silicon photonic test plug-in module as claimed in claim 5, wherein the accommodating seat further comprises a first pressure sensor disposed opposite to the movable positioning device, wherein the silicon photonic device is clamped between the movable positioning device and the first pressure sensor.

7. The silicon photonic test plug-in module as claimed in claim 1, further comprising a second pressure sensor installed between the carrier board and the floating moving device to measure an insertion force when the mating connector is connected to the silicon photonic device connector.

8. A silicon photonic test equipment, comprising:
a silicon photonic testing machine; and
a sorting machine electrically connected to the silicon photonic testing machine, wherein the sorting machine comprises:
a silicon photonic test plug-in module comprising:
a carrier board;
a floating moving device movably installed on the carrier board;
a mating connector floatingly installed in the floating moving device; and
an accommodating seat adjacent to the carrier board for fixing a silicon photonic device, wherein the mating connector automatically aligns with a silicon photonic device connector of the silicon photonic device;
a test bench testing the silicon photonic device;
a feeding module accommodating a plurality of silicon photonic devices to be tested;
a discharging module accommodating a plurality of tested silicon photonic devices;
a silicon photonic pick-and-place device disposed between the silicon photonic test plug-in module, the feeding module, and the discharging module to move the silicon photonic devices to be tested and the tested silicon photonic devices; and
a moving module, wherein the silicon photonic test plug-in module is installed on the moving module for moving the silicon photonic test plug-in module and the silicon photonic device on the silicon photonic test plug-in module to a position of the test bench.

9. The silicon photonic test equipment as claimed in claim 8, wherein the moving module comprises:
a first moving device;
a second moving device disposed perpendicular to the first moving device; and
a third moving device disposed perpendicular to the first moving device and the second moving device.

10. The silicon photonic test equipment as claimed in claim 9, wherein the third moving device comprises a moving device with two degrees of freedom.

11. The silicon photonic test equipment as claimed in claim 10, further comprising a first optical identifier installed on one side of the feeding module adjacent to the silicon photonic test plug-in module to identify a direction and an identification code of the silicon photonic device.

12. The silicon photonic test equipment as claimed in claim 11, further comprising a second optical identifier installed on the test bench to identify a structure and a position of the silicon photonic device before and after testing.

13. The silicon photonic test equipment as claimed in claim 12, further comprising a third optical identifier disposed adjacent to the discharging module to detect a lower surface and four side surfaces of a chip of the silicon photonic device.

14. The silicon photonic test equipment as claimed in claim 13, further comprising a fourth optical identifier and an optical identifier bracket, wherein the optical identifier bracket fixes the fourth optical identifier to the third moving device to detect a position of test terminals of a test head of the test bench for adjusting a position of the silicon photonic device.

15. The silicon photonic test equipment as claimed in claim 14, further comprising a fifth optical identifier disposed above the feeding module to guide the silicon photonic pick-and-place device to pick up the silicon photonic device.

16. The silicon photonic test equipment as claimed in claim 15, wherein the silicon photonic pick-and-place device comprises at least one suction nozzle to suck the silicon photonic device.

17. The silicon photonic test equipment as claimed in claim 16, wherein the at least one suction nozzle comprises:
a first suction nozzle to suck the silicon photonic device connector of the silicon photonic device; and
a second suction nozzle to suck a silicon photonic chip of the silicon photonic device.

18. The silicon photonic test equipment as claimed in claim 17, wherein the silicon photonic device further comprises a substrate and an application-specific integrated circuit, wherein the application-specific integrated circuit and the silicon photonic chip are fixed on the substrate.

19. The silicon photonic test equipment as claimed in claim 18, wherein the silicon photonic test plug-in module further comprises a plurality of probes to electrically connect the application-specific integrated circuit.

20. The silicon photonic test equipment as claimed in claim 19, wherein the silicon photonic test plug-in module further comprises a pressure plate to press against the silicon photonic device.
